(19) United States
(12) Patent Application Publication
(10) Pub. No.: US 2001/0049210 A1
(43) Pub. Date: Dec. 6, 2001

(54) 3.5 inch form factor compatible connector for 2.5 inch form factor disc drive

(75) Inventors: Frank Walter Pinteric, Niwot, CO (US); Michael Alan Maiers, Longmont, CO (US)

Correspondence Address: MERCHANT & GOULD P.C., P.O. Box 2903, Minneapolis, MN, 55402-0903, US

(73) Assignee: Seagate Technology LLC

(21) Appl. No.: 09/872,053

(22) Filed: Jun. 1, 2001

Related U.S. Application Data
(60) Provisional application No. 60/209,281, filed on Jun. 2, 2000.

(51) Int. Cl. H05K 1/00

(52) U.S. Cl. 439/76.1

(57) ABSTRACT

A system for employing a 2.5 inch form factor disc drive in computing environments configured for 3.5 inch form factor disc drives includes a 2.5 inch form factor disc drive having a disc drive printed circuit board (PCB). Attached to the PCB is a male connector defining two laterally spaced pin compartments. Located within one of the laterally spaced pin compartments are a plurality of data pins having a pin pitch of approximately 2.54 mm, such that the data pins may mate with the data pins of a conventional ATA connector configured for mating with a 3-in-1 connector of a 3.5 inch form factor disc drive.

### RELATED APPLICATIONS

This application claims priority of U.S. provisional application Serial No. 60/209,281, filed Jun. 2, 2000.

### FIELD OF THE INVENTION

This application relates generally to disc drives and more particularly to a 2.5 inch form factor disc drive having a connector suitable for use in computing environments configured for 3.5 inch form factor disc drives.

### BACKGROUND OF THE INVENTION

Data storage devices employing rigid magnetic discs (“disc drives”) are used in computer systems to record, store, and retrieve digital information. Most digital computing applications require access to a greater volume of data than can economically be stored in the random access memory of the computer's central processing unit (commonly known as “semiconductor” memory). This information can be stored on a variety of data storage devices, including disc drives, floppy-disc drives, magnetic tape drives, optical disc drives, and semiconductor memory. Disc drives, however, typically provide access to large volumes of information faster than optical disc drives, floppy-disc drives, or magnetic tape drives and at substantially lower cost than high-speed semiconductor memory.

Most disc drives incorporate the same basic technology; one or more rigid magnetic discs are attached to a spindle assembly that rotates the discs at a high constant speed around a hub. The discs (also known as recording media or disc media) are the components on which data is stored and from which it is retrieved. Each disc typically comprises a substrate of finely machined aluminum or glass with a magnetic layer of a “thin-film” metallic material. Read/write heads, mounted on an arm assembly similar in concept to that of a record player, fly extremely close to each disc surface and record data on and retrieve data from concentric tracks in the magnetic layers of the rotating discs.

Upon receiving instructions from the disc drive's electronic circuitry, a head positioning mechanism (an “actuator”) guides the heads to the selected track of a disc where data will be recorded or retrieved. The disc drive's circuitry is typically included on a printed circuit board assembly (PCB) which contains the various components necessary to control the operations of the disc drive, including the transfer of data between the computer and the discs of the disc drive. An electronic connector is typically mounted to the PCB to provide an electronic hardware interface between the disc drive and the computer. The type of electronic connector used in a given disc drive is generally dictated by two factors, the size or form factor of the disc drive and the interface specification of the disc drive.

The most common interface specification currently used in disc drives is the Advanced Technology Attachment (ATA) interface specification, sometimes referred to as IDE for Integrated Drive Electronics. The ATA specification defines the protocols used to transfer data between ATA compatible devices, such as between a disc drive and a host computer. With respect to the hardware employed in connecting to ATA compatible disc drives, there are currently two principle connector configurations based on the two most common sized disc drives, the 3.5 inch form factor disc drive and the 2.5 inch form factor disc drive. As is well known in the field of disc drives, the term “form factor” refers to the disc drive industry standard that defines the physical, external dimensions of a particular device.

For example, a 3.5 inch form factor disc drive having a standard ATA connector typically utilizes a multi-pin connector, often referred to as 3-in-1 connector, which is designed to mate with a corresponding female connector. A typical 3-in-1 connector in a 3.5 inch disc drive includes a set of forty data pins, six or eight jumper pins, and four power pins. The pin pitch, that is the center-to-center spacing of the data pins in the 3-in-1 connector, is typically 2.54 mm (0.1 inch).

A typical 2.5 inch form factor disc drive employing what is commonly referred to as a 50-pin connector. In contrast to the 3-in-1 connector typically used in 3.5 inch disc drives, the 50-pin ATA connector typically employed in 2.5 inch ATA disc drives includes forty-two data pins and two power pins, wherein two power pins are interspersed with the data pins. The pin pitch in the 50-pin connector of the 2.5 inch form factor ATA disc drive is typically 2 mm (0.078 inch).

As in most of the computing industry, a current trend in the disc drive industry is to produce smaller and faster products. In this regard, 2.5 inch form factor disc drives were initially developed primarily for use in lap-top computers, where the size and power requirements of the 3.5 inch form factor disc drives have posed problems. However, while initially designed for laptop use, 2.5 inch drives have proven to have benefits beyond those associated with the disc drive's small size and power requirements. For example, the smaller and lighter discs and actuators in the 2.5 inch form factor disc drive allow for faster disc speeds, faster disc access, and greater accuracy in head positioning than that which is attainable in a typical 3.5 inch form factor disc drive.

With the above mentioned benefits of the 2.5 inch form factor disc drive in mind, it is desirable to employ 2.5 inch form factor disc drives in environments where typical 3.5 inch form factor ATA disc drives are currently being used. Additionally, by manufacturing 2.5 inch form factor disc drives for environments where typical 3.5 inch form factor ATA disc drives are currently being used, economies of scale may be exploited, thus reducing the expenses currently related to producing 2.5 inch form factor disc drives. However, as mentioned above, the pin pitch and the arrangement of the pins in a typical 2.5 inch form factor ATA disc drive is not identical to the pin pitch and the arrangement of the pins in a typical 3.5 inch form factor ATA disc drive. As such, a typical 2.5 inch form factor ATA disc drive cannot simply be substituted for a typical 3.5 inch form factor ATA disc drive in environments designed for the use of the typical 3.5 inch form factor ATA disc drives.

Current methods of employing 2.5 inch form factor disc drives in environments intended for 3.5 inch form factor disc drives involve the use of adaptor cards and/or cables which are attached between the 2.5 inch form factor disc drive's fifty-pin, 2 mm pin pitch male connector and the forty pin, 2.54 mm pin pitch female connector to which the 3.5 inch form factor disc drive was formerly connected. One such method, uses a forty or eighty conductor ribbon cable having a 40-pin 2 mm pin pitch female connector for mating with the 40-pin 2 mm pin pitch male connector of the 2.5 inch form factor disc drive and a 40-pin 2.54 mm pin pitch male connector for mating with the 40-pin 2 mm pin pitch male connector to which the 3.5 inch form factor disc drive was formerly connected. However, while adaptors of this type do provide a physical and electrical connection between the 2 mm pin pitch male connector and the 2.54 mm pin pitch female connector, this type of connection has a number of drawbacks. Principle among these drawbacks is loss of signal integrity.

As is well known in the art, each connector or length of conductor added to a signal flow path degrades the quality of the signal. Connectors in particular are known to significantly affect signal integrity. As such, it is imperative to minimize the number of physical connections in a signal path. This is particularly true in applications, such as the disc drive, where high speed signal transmission is desired and necessary. Furthermore, adaptors of this type add additional cost to the installation and maintenance of the system employing the disc drive.

Another drawback associated with the use adaptor cards and/or cables to 2.5 inch form factor disc drives in environments intended for 3.5 inch form factor disc drives is that such cards and/or cables typically cannot be used when the disc drive is intended to plug directly into a back plane in a computer system. With respect to adaptor cards, the connections between the disc drive and the adaptor and between the adaptor and the back plane are typically not secure enough to hold the disc drive securely to the back plane.

Accordingly, there is a need for an approach of connecting a 2.5 inch form factor ATA disc drive in an environment designed for use of a 3.5 inch form factor ATA disc drive, in a manner which provides signal integrity without increasing associated costs.

### SUMMARY OF THE INVENTION

Against this backdrop the present invention has been developed. One embodiment of the present invention relates to a system for employing a 2.5 inch form factor disc drive in computing environments configured for 3.5 inch form factor disc drives. The system includes a 2.5 inch form factor disc drive having a disc drive printed circuit board (PCB) attached thereto. The PCB includes a number of PCB data contact pads. A male connector, including a number of data pins and a number of data contact pins, is operably attached to the PCB. Each of the data pins is electrically connected to an associated one of the data contact pins. The plurality of data pins includes a first row of pins having a pin pitch of approximately 2.54 mm between adjacent pins and a second row of pins. The pin pitch between the first row of data pins and the second row of data pins is approximately 2.54 mm. At least one of the data contact pins is in physical contact with one of the PCB data contact pads.

Another embodiment of the present invention relates to another system for employing a 2.5 inch form factor disc drive in a computing environment configured for 3.5 inch form factor disc drive. The system includes a 2.5 inch form factor disc drive having a disc drive printed circuit board (PCB). The PCB includes a plurality of PCB data contact pads and a plurality of PCB power contact pads. A male connector includes a main body defining two laterally spaced pin compartments. Positioned within a first of the laterally spaced pin compartment are number of data pins. Extending from the main body are a number of data contact pins. Each of the data contact pins is electrically connected to an associated one of the data pins. Each of the data contact pins is bonded to a respective PCB data contact pad. Additionally, a number of power pins are positioned within a second of the laterally spaced pin compartments. A plurality of power contact pins extend from the main body, each of the plurality of power contact pins being in electrical connection with an associated power pin. Finally, each of the power contact pins is bonded to a respective PCB power contact pad.

These and various other features as well as advantages which characterize the present invention will be apparent from a reading of the following detailed description and a review of the associated drawings.

### BRIEF DESCRIPTION OF THE DRAWINGS

FIG. 1 is a perspective view of a disc drive incorporating an embodiment of the present invention.

FIG. 2 is a simplified functional block diagram of various elements of the disc drive shown in FIG. 1.

FIG. 3 is a perspective view showing a lower surface of a disc drive printed circuit board (PCB) and a connector of the disc drive of FIG. 1.

FIG. 4 is an exploded perspective view of the disc drive of FIG. 1, specifically illustrating the disc drive, the PCB, and the connector, in accordance with an embodiment of the present invention.

FIG. 5 is a perspective view of the connector of the disc drive of FIG. 1, in accordance with an embodiment of the present invention.

FIG. 6 is front plan view of the connector shown in FIG. 5, showing the pin layout of the connector in accordance with an embodiment of the present invention.

FIG. 7 is a perspective view showing the connector of FIG. 5 connected to an upper surface of the surface of the PCB of FIG. 4, in accordance with an embodiment of the present invention.

FIG. 8 is a partial plan view of the disc drive, PCB, and connector of the disc drive shown in FIG. 1, taken in the plane of 8-8.

FIG. 9 is a perspective view of a 3.5 inch form factor disc drive incorporating a standard ATA 3-in-1 connector.

FIG. 10 is a front plan view of the 3-in-1 connector of FIG. 9, showing the pin layout of the connector.

FIG. 11 is a perspective view of a 2.5 inch form factor disc drive incorporating a standard ATA 50-pin connector.

FIG. 12 is a front plan view of 50-pin connector of FIG. 11, showing the pin layout of the connector.

FIG. 13 is a perspective of a power cable suitable for use in relation to the disc drive of FIG. 1, in accordance with an embodiment of the present invention.

### DETAILED DESCRIPTION

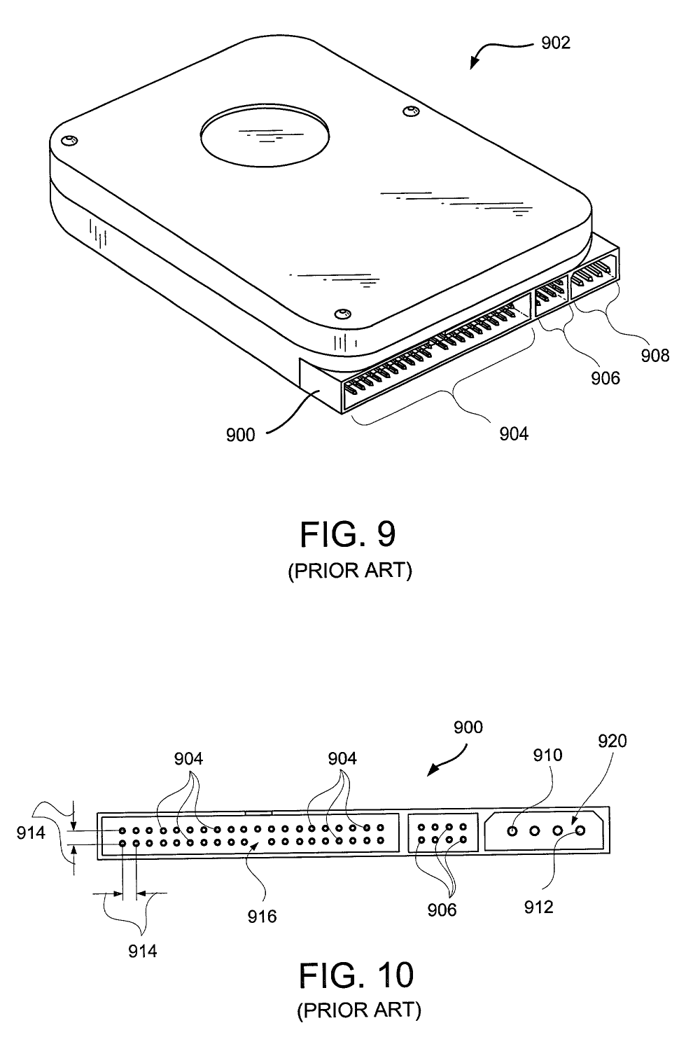

To facilitate an understanding of the various embodiments of the present invention, a brief description of standard ATA connectors for 3.5 inch form factor disc drives and 2.5 inch form factor disc drives will now be given. A 3.5 inch form factor disc drive having a standard ATA connector typically utilizes a multi-pin connector, often referred to as 3-in-1 connector, which is designed to mate with a corresponding female connector. As shown in FIGS. 9 and 10, a typical 3-in-1 connector 900 in a 3.5 inch disc drive 902 includes a set of forty data pins 904, six or eight jumper pins 906, and four power pins 908. The forty data pins 904 are used for data transfer. The assignment of the pins, that is which signals are assigned to which pin, is determined by the ATA specification. The six or eight jumper pins are typically used to configure the disc drive for master, slave, or single-drive operation. The four power pins 908 provide power to the disc drive at either 5 volts DC 910 or 12 volts DC 912. Additionally, one of the data pins 916 is typically removed for polarity. As shown in FIG. 10, the pin pitch 914, that is the center-to-center spacing of the data pins in the 3-in-1 connector, is typically 2.54 mm (0.1 inch).

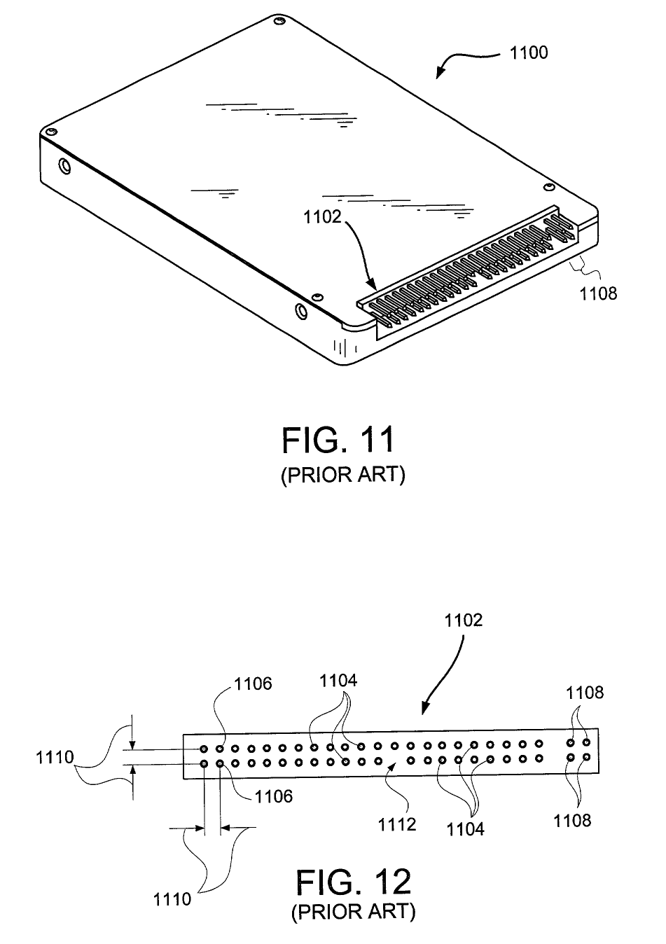

FIGS. 11 and 12 illustrate a typical 2.5 inch form factor disc drive 1100 employing what is commonly referred to as a 50-pin connector 1102. In contrast to the 3-in-1 connector typically used in 3.5 inch disc drives, the 50-pin ATA connector 1102 typically employed in 2.5 inch ATA disc drives includes forty-two data pins 1104 and two power pins 1106, wherein two power pins 1106 are interspersed with the data pins 1104. In addition to the data pins 1104 and power pins 1106, the 2.5 inch form factor ATA disc drive also typically includes four jumper pins 1108, which are used to configure the disc drive for master, slave, or single-drive operation. Additionally, one of the data pins 1112 is typically removed for polarity. The assignment of the pins, that is which signals are assigned to which pin, is determined by the ATA specification. The pin pitch 1110 in the 50-pin connector 1102 of the 2.5 inch form factor ATA disc drive 1100 is typically 2 mm (0.078 inch).

As described above, the pin pitch and arrangement of the pins of a typical 2.5 inch form factor ATA disc drive are not identical to the pin pitch and arrangement of the pins of a typical 3.5 inch form factor ATA disc drive. As such, a typical 2.5 inch form factor ATA disc drive cannot simply be substituted for a typical 3.5 inch form factor ATA disc drive in systems designed for use the use of the typical 3.5 inch form factor ATA disc drive. That is, the connector on a typical 2.5 inch form factor ATA disc drives is not compatible with the disc drive connector in a systems designed for use the use of the typical 3.5 inch form factor ATA disc drive. Furthermore, as described above, current methods of providing connectivity between 2.5 inch form factor disc drives in environments designed for the use of 3.5 inch form factor disc drives typically degrade signal quality and add additional costs to such systems. Various embodiments of the present invention, as described herein, address the connector compatibility problem described in a manner which provides signal integrity without increasing associated costs.

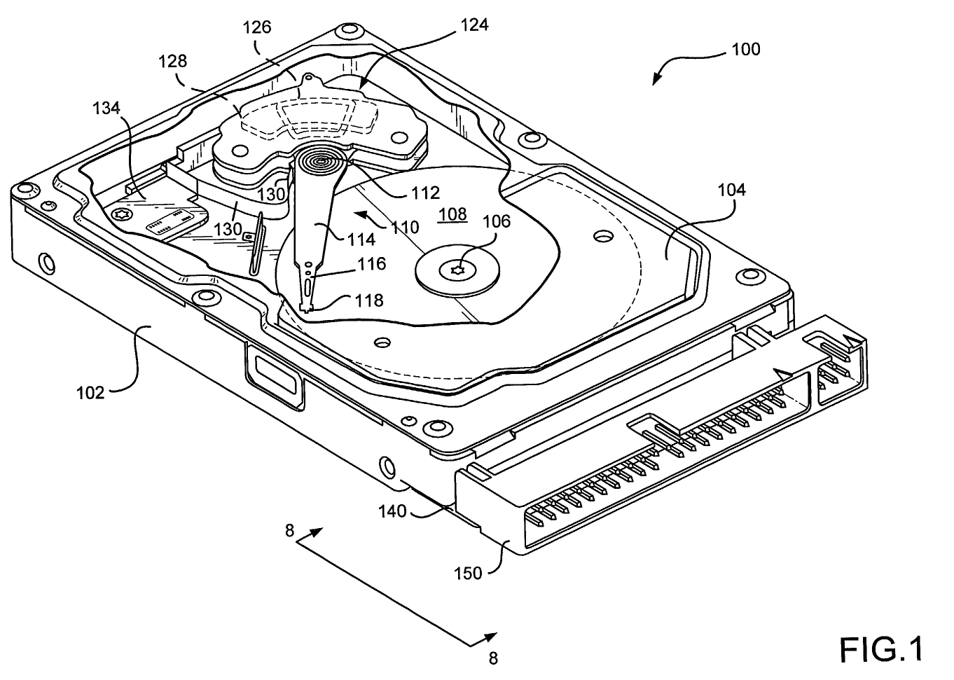

A disc drive 100 constructed in accordance with a preferred embodiment of the present invention is shown in FIG. 1. The disc drive 100 includes a base 102 to which various components of the disc drive 100 are mounted. A top cover 104, shown partially cut away, cooperates with the base 102 to form an internal, sealed environment for the disc drive in a conventional manner. The components include a spindle motor 106 which rotates one or more discs 108 at a constant high speed. Information is written to and read from tracks on the discs 108 through the use of an actuator assembly 110, which rotates during a seek operation about a bearing shaft assembly 112 positioned adjacent the discs 108. The actuator assembly 110 includes a plurality of actuator arms 114 which extend towards the discs 108, with one or more flexures 116 extending from each of the actuator arms 114. Mounted at the distal end of each of the flexures 116 is a head 118 which includes an air bearing slider enabling the head 118 to fly in close proximity above the corresponding surface of the associated disc 108.

During a seek operation, the track position of the heads 118 is controlled through the use of a voice coil motor (VCM) 124, which typically includes a coil 126 attached to the actuator assembly 110, as well as one or more permanent magnets 128 which establish a magnetic field in which the coil 126 is immersed. The controlled application of current to the coil 126 causes magnetic interaction between the permanent magnets 128 and the coil 126 so that the coil 126 moves in accordance with the well known Lorentz relationship. As the coil 126 moves, the actuator assembly 110 pivots about the bearing shaft assembly 112, and the heads 118 are caused to move across the surfaces of the discs 108.

A flex assembly 130 provides the requisite electrical connection paths for the actuator assembly 110 while allowing pivotal movement of the actuator assembly 110 during operation. The flex assembly includes a printed circuit board 132 to which head wires (not shown) are connected; the head wires being routed along the actuator arms 114 and the flexures 116 to the heads 118. The printed circuit board 132 typically includes circuitry for controlling the write currents applied to the heads 118 during a write operation and a preamplifier for amplifying read signals generated by the heads 118 during a read operation. The flex assembly terminates at a flex bracket 134 for communication through the base 102 to a disc drive printed circuit board (PCB) 140 mounted to the bottom side of the disc drive 100. Also shown in FIG. 1 is a connector 150 constructed in accordance with an embodiment of the present invention. The connector is preferably mechanically and electrically coupled to the PCB 140, as described in greater detail below.

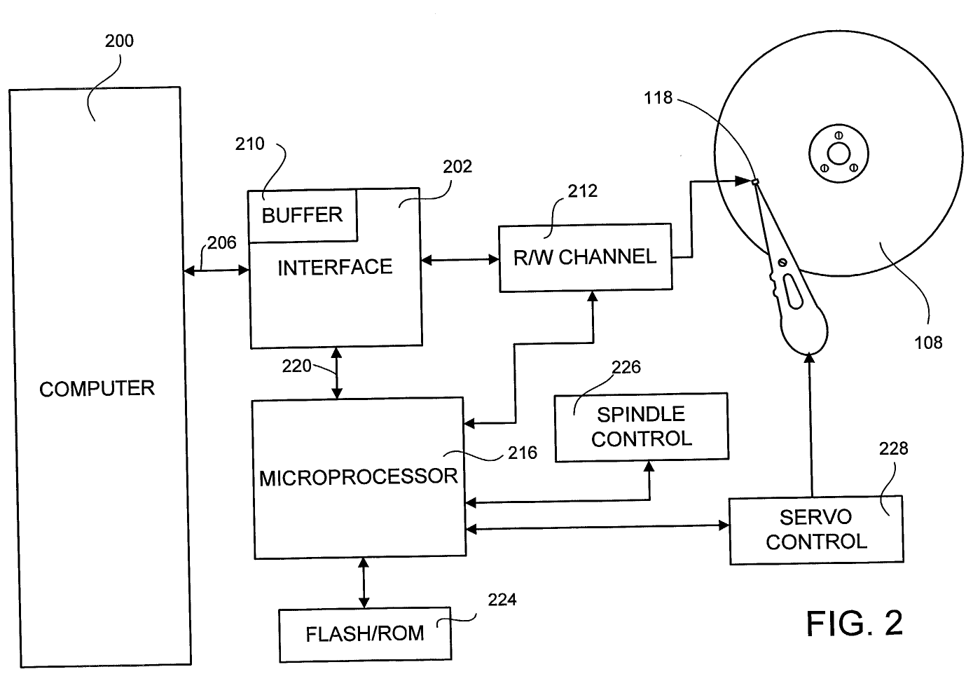

Referring now to FIG. 2, shown therein is a functional block diagram of the disc drive 100 of FIG. 1, generally showing the main functional circuits which are typically resident on the disc drive PCB 140 and which are used to control the operation of the disc drive 100. As shown in FIG. 2, a computer 200 is operably connected 206 to an interface application specific integrated circuit (interface) 202. As described in greater detail below, the functional circuits of the disc drive 100 are connected to the computer 200 via the connector 250. The interface 202 typically includes an associated buffer 210 which facilitates high speed data transfer between the computer 200 and the disc drive 100. Data to be written to the disc drive 100 are passed from the host computer to the interface 202 and then to a read/write channel 212, which encodes and serializes the data and provides the requisite write current signals to the heads 118. To retrieve data that has been previously stored by the disc drive 100, read signals are generated by the heads 118 and provided to the read/write channel 212, which performs decoding and error detection and correction operations and outputs the retrieved data to the interface 202 for subsequent transfer to the computer 200. Such operations of the disc drive 100 are well known in the art and are discussed, for example, in U.S. Pat. No. 5,276,662 issued Jan. 4, 1994 to Shaver et al.

As also shown in FIG. 2, a microprocessor 216 is operably connected 220 to the interface 202. The microprocessor 216 provides top level communication and control for the disc drive 100 in conjunction with programming for the microprocessor 216 which is typically stored in a non-volatile microprocessor memory (MEM) 224. The MEM 224 can include random access memory (RAM), read only memory (ROM) and other sources of resident memory for the microprocessor 216. Additionally, the microprocessor 216 provides control signals for spindle control 226, and servo control 228.

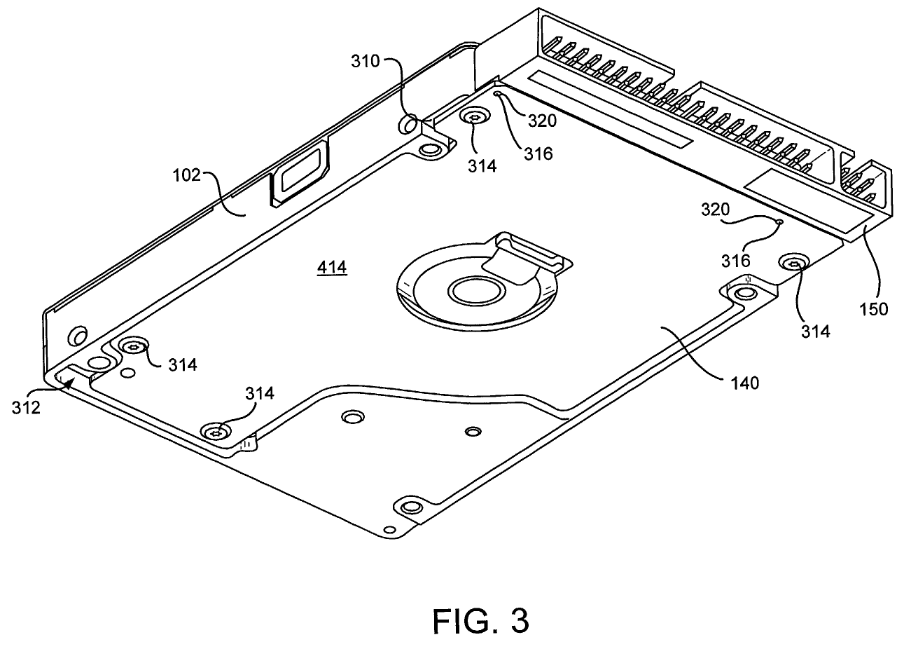

FIG. 3 illustrates a perspective view of the bottom of the disc drive 100 shown in FIG. 1. As shown in FIG. 3, the disc drive base 102 preferably includes a lower surface 310 having a recess 312 formed therein. The PCB 140 is operably held in position within the recess 312 of the base 102. The PCB 140 is preferably held in position generally in a plane parallel with the lower surface 310 of the base 102 by a plurality of screws 314, or some other fastening mechanism. As also shown in FIG. 3, a pair of solder pins 316 extends from the connector 150 and into or through the PCB 140 via a pair of apertures or holes 320 in or through the PCB 140. As described more fully below, the solder pins 316 assist in holding the connector 150 more securely to the PCB 140, and thus to the disc drive 100.

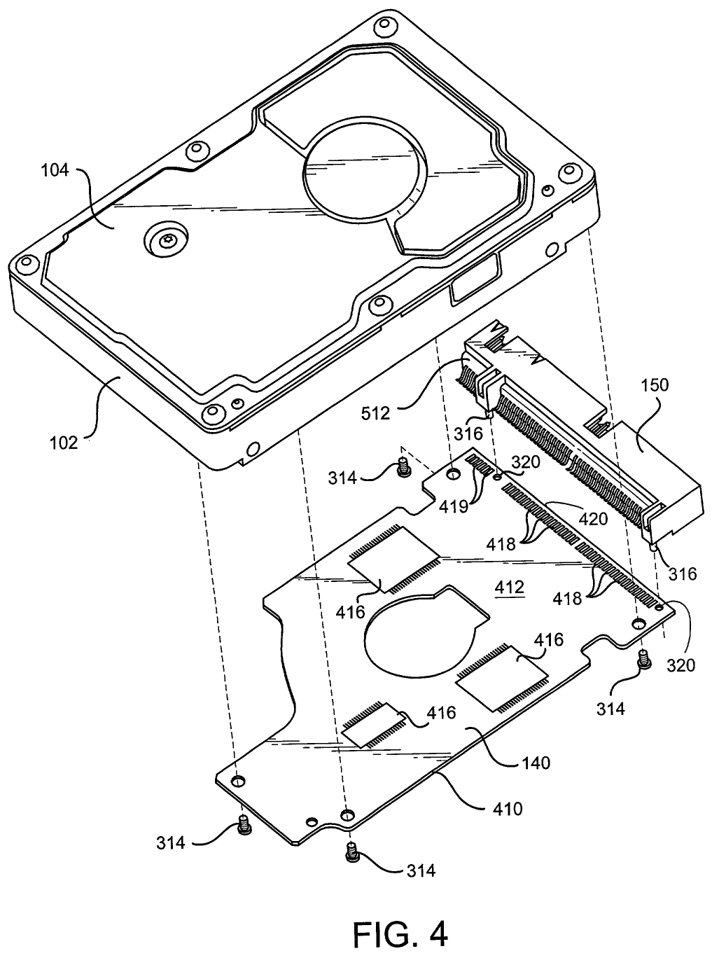

Referring now to FIG. 4, an exploded view of the disc drive 100 is shown including the base 102 and the top cover 104, the PCB 140, and the connector 150. The PCB 140 preferably comprises a firm planar substrate 410 having an upper surface 412 and lower surface 414 (FIG. 3). Affixed or imprinted on the upper surface 412 and/or the lower surface 414 of the PCB 140 are various circuitry and components 416 necessary for the functioning of the disc drive 100. Additionally, a row of PCB data contact pads 418 and a row of power contact pads 419, which are electrically connected to the various circuitry and components 416 of the PCB 140, are located adjacent to an outer edge 420 of the upper surface 412 of the PCB 140.

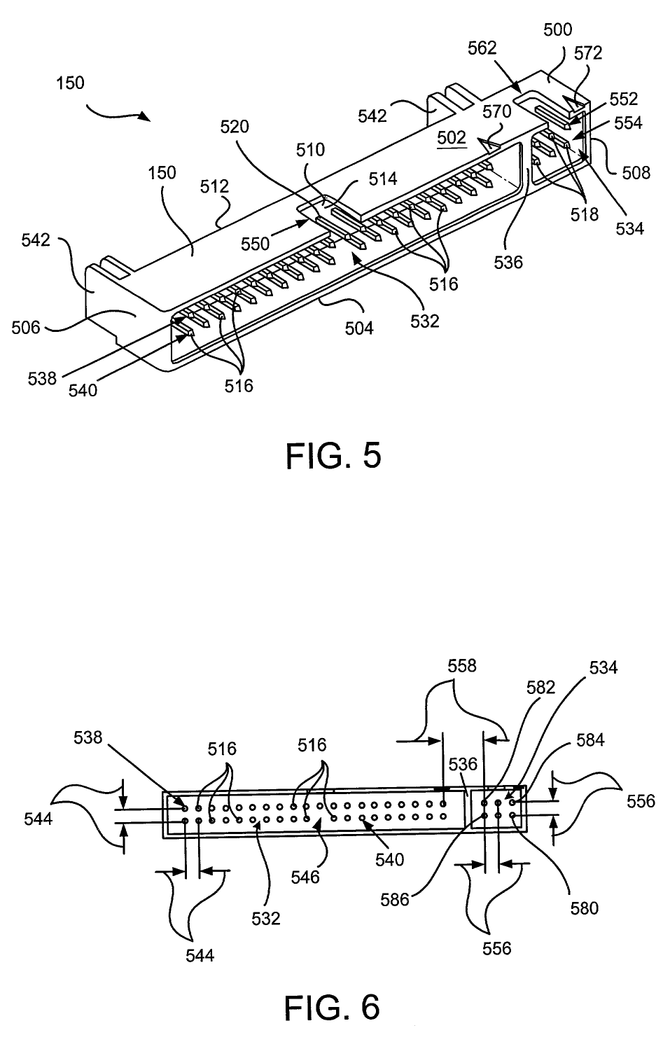

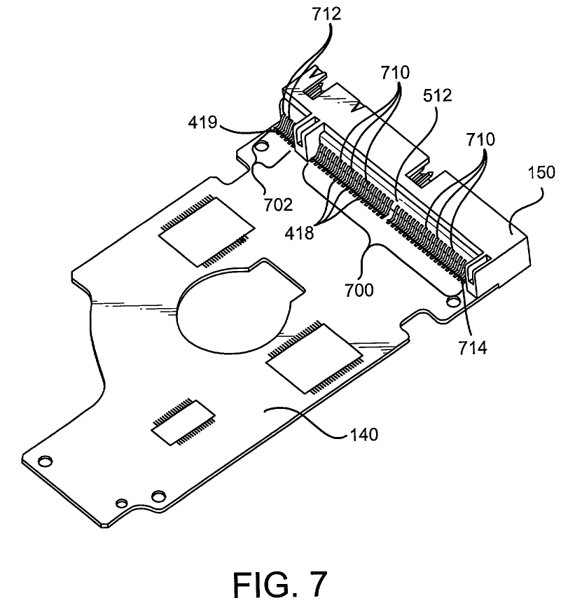

In general, the connector 150 is employed to provide an electrical connection point between the various circuitry 416 of the disc drive 100 and an external device, such as computer 200. FIGS. 5 and 6 are perspective and front elevation views, respectively, of the connector 150 in accordance with an embodiment of the present invention. The connector 150 has a generally cubical elongate body 500 made of an electrically insulating material defined by a peripheral surface including a generally planar upper part 502, a generally planar bottom part 504, end parts 506 and 508, and an pin supporting wall 510. The pin supporting wall 510 includes a rear surface 512 (FIGS. 4 and 7) and a forward surface 514, which supports a set of forwardly-extended data pins 516 and a set of forwardly extending power pins 518. Each of the data pins 516 and power pins 518 includes a proximal end 520 held within the pin supporting wall 510 and a distal end extending from the pin supporting wall 510. Additionally, each of the data pins 516 and power pins 518 is electrically connected at its proximal end 520 to a corresponding PCB contact pin 710 (FIG. 7).

As best seen in the front elevation view of FIG. 6, the data pins 516 and power pins 518 are disposed within separate laterally spaced compartments 532 and 534, respectively. An internal partition 536, oriented in a height-wise direction, separates the two laterally separated compartments, a data pin compartment 532 and a power pin compartment 534. The data pins 516 are arranged in two parallel rows, an upper row 538 and lower row 540, within the data pin compartment 532. The pin pitch 544 between the upper row 538 of data pins and the lower row 540 of data pins is preferably 2.54 mm. The upper row 538 contains twenty-two evenly spaced data pins 516, wherein the pin pitch 544 between the adjacent pins in the upper row 538 is preferably 2.54 mm, wherein the pin pitch 544 between the adjacent pins in the lower row 540 is preferably 2.54 mm.

As shown in FIG. 6, one of the data pins 516 in the lower row 540 of the data pin compartment 532, at a location identified by the numeral “546” is shown missing. This is intended to be exemplary, and indicative of the fact that one or more such pins may be omitted as deemed appropriate. In addition to the removal of one or more of the data pins as described, there is also preferably a polarizing “cut-out” 550 in the upper part 502 of the connector adjacent the data pin compartment 532, which is shaped and sized to receive therein a correspondingly shaped and located extension of a female data connector (not shown). As with the removal of the data pin, the cut-out 550 polarizes the connector such that the female data connector corresponding to the male connector 150 may be connected to the data pins 516 located in the data pin compartment 532 of the male connector 150 in only one manner.

Preferably, the assignment of the data pins 516, that is which signals are assigned to which pin, is the same as the assignment of the data pins in connector of a typical 3.5 inch form factor disc drive, such as that shown and described with respect to FIG. 9, as determined by the ATA specification.

As with the data pins 516, the power pins 518 are arranged in two parallel rows, an upper row 552 and lower row 554, within the power pin compartment 534. The upper row 552 of power pins 518 preferably contains three evenly spaced power pins 518. The lower row 554 of power pins 518 also preferably contains three evenly spaced pins 518. The pin pitch 556 between the power pins 518 is preferably 2.54 mm. Additionally, the pin pitch between the data pins 516 and the power pins 528 is preferably a multiple of 2.54 mm (0.1 inch). For example, as shown in FIG. 6, the pin pitch 558 between the data pins 516 and the power pins 528 is preferably 5.08 mm (0.2 inch).

As shown in FIG. 6, the power pins 518 are preferably arranged with two 5 volt power pins 580 and 582 located in opposite corners from one another in the power pin compartment 534. The use of two power pins 580 and 582 allows a greater current carrying capacity than would be available if only a single power pin were to be used. Likewise, two ground pins 584 and 586 are also preferably arranged in opposite corners from one another in the power pin compartment 534. Configured in this manner, a power cable 1300 (FIG. 13) cannot be inserted in an improper manner.

As shown in FIGS. 5 and 6, there is preferably a polarizing “cut-out” 562 in the upper part 502 of the connector adjacent the power pin compartment 534, which is shaped and sized to receive therein a correspondingly shaped and located extension 1320 of a female power connector 1300 (FIG. 13). The cut-out 562 polarizes the connector such that the female power connector corresponding to the power pin compartment 534 of the male connector 150 may be connected to the power pins 518 located in the power pin compartment 534 of the male connector 150 in only one manner.

In addition to the polarizing cut-outs 550 and 562 and the missing data pin 546 to indicate polarity, the connector 150 also preferably includes a notch 570 in the upper part 502 of the connector adjacent the data pin compartment 532. The notch 570 preferably indicates where the first of the data pins 516 is located in accordance with the ATA specification.

As shown in FIG. 7, the connector 150 includes a first set 700 of resilient, electrically conductive, J-shaped PCB contact pins 710 extending downward and away from the rear surface 512 of the pin supporting wall 510. Each of the first set 700 of PCB contact pins 710 is connected via an electrical conductor (not shown) to a corresponding data pin 516. Additionally, the connector 150 also includes a second set 702 of J-shaped PCB contact pins 712 extending downward and away from the rear surface 512 of the pin supporting wall 510. Each of the second set 700 of PCB contact pins 712 is connected via an electrical conductor (not shown) to a corresponding power pin 518. Each of the J-shaped contact pins 710 and 712 has a contact portion 714. As shown in FIG. 7, when the connector 150 is mounted to the PCB 140 the contact portions 714 each of the J-shaped PCB contact pins 710 and 712 is aligned with, and comes in contact with, a respective PCB contact pad 418. The resilient nature of the J-shaped PCB contact pins 710 and 712 allows each of the J-shaped PCB contact pins 710 and 712 to act as a spring, thus keeping the contact portion 570 of each of the data contact pins 710 in firm contact with the respective PCB data contact pads 418 and the contact portion 570 of the power contact pins 712 in firm contact with the respective power contact pads 419 when the connector 150 is mounted to the PCB 140. Additionally, each of the PCB data contact pins 710 and power contact pins 712 is preferably soldered to a corresponding data contact pad 700 or power contact pad 702, respectively, to achieve a excellent electrical connection between each of the contact pins 710 and 712 and their corresponding PCB data contact pads 418 and PCB power contact pads 419, respectively. The connection of the data contact pins 710 and power contact pins 712 to the contact pins to their corresponding PCB data contact pads 418 and PCB power contact pads 419, also provides a firm physical connection the connector 150 and the PCB 140.

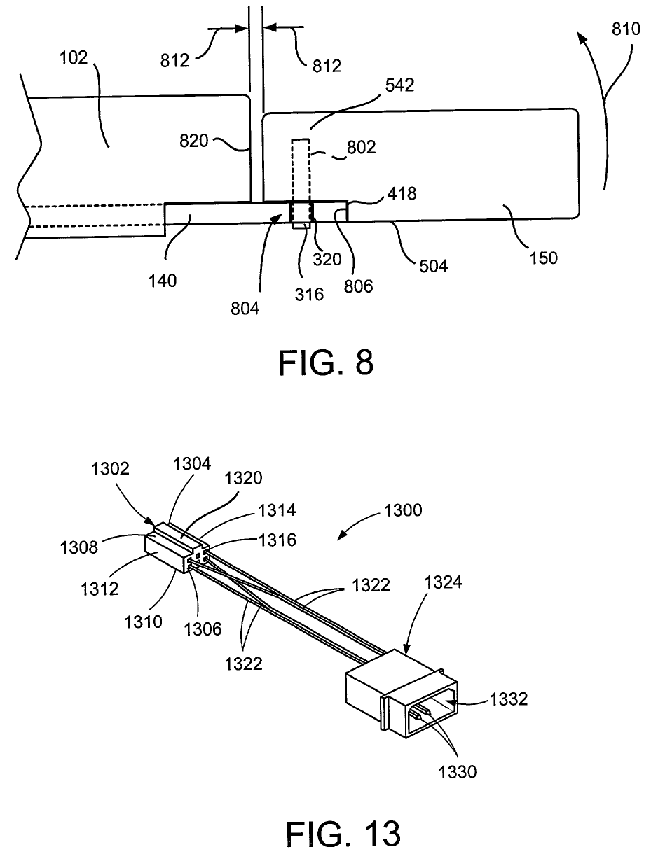

Extending from, and integral with, the rear surface 512 of the pin supporting wall 510 are a pair of attachment tabs 542. As shown in FIGS. 4 and 8, each attachment tab 542 has extending therefrom, a solder pin 316. As shown best in FIG. 8, an upper end 802 of each solder pin 316 is held firmly within an attachment tab 542, while a lower end of each solder pin extends from a lower surface 804 of an attachment tab 542 and into a corresponding aperture or hole 320 in the PCB 140. The solder pins 316 may be composed of a metallic material which may be held within the holes 320 in the PCB 140. Alternatively, the solder pins may be made of metal or some other substance and soldered, bonded, friction fit, or adhesively held, within the holes 320. For example, the solder pins may be formed integrally with the material of the connector body 500.

As shown in FIG. 8, the PCB 140 preferably extends beyond a front wall 820 of the disc drive base 102. As discussed, the connector 150 is held in contact with the PCB 140 by both the solder pins 316 and the soldering of the PCB contact pins 710 and 712 to corresponding PCB contact pads 418. As shown in FIG. 8, the bottom part 504 of the connector 150 includes a recessed portion 804 having a front wall 806 which abuts the outer edge 418 of the PCB 140 when the connector is positioned on the PCB 140. The recessed portion 804 and the front wall 806 provide a guide which promotes the accurate and stable attachment of the connector 150 to the PCB 140. Additionally, as shown in FIG. 8, when the connector 150 is attached to the PCB 140, the attachment tabs 542 or in a position near 812 the base 102 of the disc drive 100. Positioned as such, the attachment tabs 542 function as a stop to prevent excessive flexing or movement of the connector 150 in the direction of the arrow 810 as shown in FIG. 8. That is, when the connector is moved in the direction of arrow 810, a portion of the attachment tab(s) 542 will come in contact with the front wall 820 of the disc drive base 102, thus inhibiting further movement of the connector 150 in the direction of the arrow 810.

Together, the soldering of the PCB contact pins 710 and 712 to corresponding PCB contact pads 418, the attachment of the solder pins 316 to the PCB 140, and the placement of the attachment tabs 542 near the base 102 of the disc drive 100 provide a sturdy and reliable connection of the connector 150 to the PCB 140, and thus to the disc drive 100.

Once the connector 150 has been connected to the PCB 140, as described, the disc drive may then be connected in an environment designed for use of a 3.5 inch form factor ATA disc drive. This attachment may be made either with a standard 40 or 80-pin ATA compliant cable or, alternatively, the connector may be plugged directly into a back plane in a computer system.

Power may be provided to the disc drive in one embodiment of the present invention by a cable, such as the cable 1300 shown in FIG. 13. The cable 1300 preferably includes a 6-pin female connector 1302 electrically connected by four wires or leads 1322 to a male connector 1324. The female connector 1302 has an elongate generally cubical body of a length, a width, and height to match the power pin compartment 534 of the connector 150. The body of the female connector 1302 has a front face 1304, a rear face 1306 and a peripheral surface comprising an upper surface 1308, a lower surface 1310, and first 1312 and second 1314 side parts. In one embodiment of the female connector 1302, a polarizing extension 1320 portion projects outwardly of the upper surface 1308 so as to mate with the polarizing “cut-out” 562 in the upper part 502 of the connector 150 adjacent the power pin compartment 534.

Six open-ended pin-receptacles 1316 are mounted in and extend through the body of the female connector 1302 from the front face 1304 to the rear face 1306. Each of the pin-receptacles 1316 is arrayed to receive through the front face 1304 of the female connector 1302 a respective power pin 518 of the connector 150. Extending from, and electrically connected to, the four of the pin receptacles 1316, via the rear face 1306, are the four wires or leads 1322. These four wires 1322 extend to, and electrically connect with, two pins 1326 located in the male connector 1324.

As shown in FIG. 13, the male connector 1324 includes two power pins 1330 located within a power pin compartment 1332 that is preferably sized and shaped similarly to the power pin compartment 920 of a standard 3-in-1 type connector, as shown in FIG. 10. In this way, the female portion of a standard power connector configured to mate with a 3-in-1 type connector power pin compartment may be inserted, and retained within, the power pin compartment 1332 of the male connector 1324. It should be noted, unlike the four power pins 908 typically included in a standard 3-in-1 male connector, the male portion of the connector 1324 includes only two power pins, as the 2.5 inch form factor disc drive 100 is preferably configured to accept only 5 volts. As such, the two 12 volt power pins of the standard 3-in-1 connector are not needed in the male connector 1324.

In summary, in view of the foregoing discussion it will be understood that one embodiment of the present invention relates to a system for employing a 2.5 inch form factor disc drive in computing environments configured for 3.5 inch form factor disc drives. In this embodiment of the present invention, the system includes a 2.5 inch form factor disc drive (such as 100) having a disc drive PCB (such as 140), including a plurality of PCB data contact pads (such as 418). Also included in the system is a male connector (such as 140) operably attached to the PCB. Preferably, the male connector including a number of data pins (such as 516) and a number of data contact pins (such as 518). Each of the data pins is preferably electrically connecting to one of the data contact pins. In this embodiment, the data pins include a first row of data pins (such as 538) having a pin pitch of approximately 2.54 mm. The data pins also preferably include a second row of pins (such as 540), wherein the pin pitch between the first row of data pins and the second row of data pins is approximately 2.54 mm. At least one of the data contact pins is preferably in physical contact with one of the PCB data contact pads. The male connector preferably includes no more than forty data pins.

In this embodiment of the invention, the first row of data pins preferably includes twenty data pins (such as 540) and the second row of data contact pins preferably includes a first group of ten data pins (such as 540) having a pin pitch of approximately 2.54 mm between adjacent pins and a second group of nine data pins having a pin pitch of approximately 2.54 mm between adjacent pins. Additionally, the pin pitch between adjacent data pins in the first group of data pins and the second group of data pins is approximately 5.08 mm.

The PCB in this embodiment of the present invention preferably also includes a number of PCB power contact pads (such as 419). Additionally, the male connector further preferably includes a number of power pins (such as 518) and a corresponding number of power contact pins (such as 419), wherein each of the power pins is preferably electrically connected to an associated one of the power contact pins. The plurality of power pins preferably includes a first row (such as 552) of power pins having a pin pitch of approximately 2.54 mm between adjacent pins and a second row of power pins (such as 554) having a pin pitch of approximately 2.54 mm between adjacent pins. Also, the pin pitch between the first row of power pins and the second row of power pins is approximately 2.54 mm. At least one of the power contact pins is preferably in physical contact with one of the PCB power contact pads. The pin pitch between adjacent power pins and data pins is approximately 5.08 mm (such as 558).

In this embodiment of the present invention, the male connector may include a main body portion (such as 500) composed of electrically insulating material. The main body portion includes a generally planar upper part (such as 502), a generally planar bottom part (such as 504), a forward surface (such as 510), and a rear surface (such as 512). Additionally, the rear surface preferably has an attachment tab (such as 542) extending therefrom. In this embodiment, the male connector is operably attached to the PCB via the attachment tab and the data contact pins.

In this embodiment, the attachment tab preferably includes a solder pin (such as 316) extending therefrom, and the PCB preferably includes an aperture (such as 320) sized to receive a portion of the solder pin. In this embodiment, the attachment tab is operably attached to the PCB via the solder pin and the solder pin is preferably bonded to the PCB.

In an embodiment of the present invention, the disc drive preferably includes a base (such as 102) having a front wall (such as 820) and a lower surface (such as 310). In this embodiment, the PCB is preferably connected to the lower surface of the base in a manner such the PCB extends beyond the front wall of the base and away from disc drive. In this embodiment, the attachment tab is preferably positioned adjacent to the front wall of the base.

In another embodiment of the present invention, the main body portion of the male connector preferably includes two laterally spaced pin compartments (such as 532 and 534) which are integral with the main body portion and extend from the forward surface of the main body portion. The data pins are preferably positioned within a first of the laterally spaced pin compartments (such as 532) and the power pins are positioned entirely within a second of the laterally spaced pin compartments (such as 534).

In yet another embodiment of the present invention the system further includes a power cable (such as 1300) having a female connector (such as 1302) including a set of pin-receptacles (such as 1316), a male connector (such as 1324) including a set of male pins (such as 1330), and one or more electrical conductors (such as 1322) electrically connecting each of the pins in the set of male pins to one or more of the pin receptacles. The female connector in this embodiment is sized to fit within the second of the laterally spaced pin compartments and the male connector is sized for mating with a female connector configured to mate with a 3-in-1 ATA interface power connector compartment.

Another embodiment of the present invention comprises another system for employing a 2.5 inch form factor disc drive in computing environments configured for 3.5 inch form factor disc drives. The system includes a 2.5 inch form factor disc drive (such as 100) having a disc drive printed circuit board (PCB) (such as 140) including a plurality of PCB data contact pads (such as 710) and a plurality of PCB power contact pads (such as 712). Also included is a male connector (such as 150) comprising a main body (such as 500) defining two laterally spaced pin compartments (such as 532 and 534). Positioned within the first laterally spaced compartment (such as 532) are a number of data pins (such as 516). Positioned within the second laterally spaced compartment (such as 534) are a number of power pins (such as 518). A plurality of data contact pins Positioned within the first laterally spaced compartment (such as 532) are a number of data pins (such as 710) preferably extend from the main body. Each of the of the data contact pins is preferably electrically connected to an associated one of the data pins. Each of the data contact pins is preferably bonded to a respective PCB data contact pad. Positioned within a second of the laterally spaced pin compartments are a number of power pins (such as 518). A number of power contact pins (such as 712) preferably extend from the main body. Additionally, each of the power contact pins is preferably electrically connected to an associated power pin. Each of the power contact pins is bonded to a respective PCB power contact pad.

In this embodiment of the present invention, the data pins preferably include a first row of data pins (such as 538) having a pin pitch of approximately 2.54 mm. Also included in this embodiment is a second row of data pins (such as 540). The pin pitch between the first row of data pins and the second row of data pins is preferably approximately 2.54 mm. The power pins in this embodiment preferably include a first row of power pins (such as 552) having a pin pitch of approximately 2.54 mm and a second row of power pins (such as 554) having a pin pitch of approximately 2.54 mm. The pin pitch between the first row of power pins and the second row of power pins is also preferably approximately 2.54 mm.

Also, preferably included in this embodiment of the present invention is a power cable (such as 1300) having a female connector (such as 1302) including a set of pin-receptacles (such as 1316), a male connector (such as 1324) including a set of male pins (such as 1330), and one or more electrical conductors (such as 1322) electrically connecting each of the pins in the set of male pins to one or more of the pin receptacles, wherein the female connector is sized to fit within the second of the laterally spaced pin compartments. The male connector in this embodiment is sized for mating with a female connector configured to mate with a 3-in-1 ATA interface power connector compartment.

Yet another embodiment of the present invention is directed to a system for employing a 2.5 inch form factor disc drive in a computing environment configured for 3.5 inch form factor disc drives. This embodiment includes a 2.5 inch form factor disc drive (such as 100) including a base (such as 102) and a disc drive printed circuit board (PCB) (such as 140) attached to the base. The PCB in this embodiment includes a plurality of data contact pads (such as 418) and a plurality of power contact pads (such as 419). Also included in this embodiment is a data connecting means (such as 150) for electrically connecting the data contact pads of the PCB to data pin receptacles of a female connector configured to mate with a ATA 3-in-1 connector. The system of this embodiment further preferably includes a power connecting means (such as 1300) for electrically connecting the power contact pads of the PCB to power pin receptacles in a female ATA 3-in-1 connector. Additionally, the data connecting means preferably includes a number of data pins having a pin pitch of 2.54 mm.

It will be clear that the present invention is well adapted to attain the ends and advantages mentioned as well as those inherent therein. While presently preferred embodiments have been described for purposes of this disclosure, various changes and modifications may be made which are well within the scope of the present invention. For example, while two attachment tabs 542 are shown and described, it will be understood that any number of extension tabs may be used. Also, while an internal partition 536 is described separating the data pin compartment 532 and the power pin compartment 534, it will be understood that the internal partition 536 may be removed. Likewise, it is to be understood that although the power connector 1300, shown and described with respect to FIG. 13, includes six pin-receptacles 1316, two power pins 1330, and four wires 1322, this particular arrangement of elements may be modified, provided that the structure of the power connector 1300 is such that it will correctly mate with the female power receptacle configured for mating with a standard ATA 3-in-1 power connector compartment of a 3.5 inch form factor disc drive. Numerous other changes may be made which will readily suggest themselves to those skilled in the art and which are encompassed in the spirit of the invention disclosed and as defined in the appended claims.

What is claimed is:

1. A system for employing a 2.5 inch form factor disc drive in computing environments configured for 3.5 inch form factor disc drives, comprising:
a 2.5 inch form factor disc drive having a disc drive printed circuit board (PCB), the PCB including a plurality of PCB data contact pads; and
a male connector operably attached to the PCB, the male connector including a plurality of data pins and a plurality of data contact pins, each of the plurality of data pins electrically connecting to an associated one of the plurality of data contact pins, the plurality of data pins including a first row of data pins having a pin pitch of approximately 2.54 mm between adjacent pins and a second row of data pins, wherein the pin pitch between the first row of data pins and the second row of data pins is approximately 2.54 mm, and wherein at least one of the data contact pins is in physical contact with one of the plurality of PCB data contact pads.

2. The system of claim 1, wherein the male connector includes no more than forty data pins.

3. The system of claim 1, wherein the first row of data pins includes twenty data pins, wherein the second row of data contact pins includes a first group of ten data pins having a pin pitch of approximately 2.54 mm between adjacent pins and a second group of nine data pins having a pin pitch of approximately 2.54 mm between adjacent pins, and wherein the pin pitch between adjacent data pins in the first group of data pins and the second group of data pins is approximately 5.08 mm.

4. The system of claim 1, wherein the PCB further includes a plurality of PCB power contact pads, and wherein the male connector further includes a plurality of power pins and a plurality of power contact pins, each of the plurality of power pins electrically connecting to an associated one of the plurality of power contact pins, the plurality of power pins including a first row of power pins having a pin pitch of approximately 2.54 mm between adjacent pins and a second row of power pins having a pin pitch of approximately 2.54 mm between adjacent pins, wherein the pin pitch between the first row of power pins and the second row of power pins is approximately 2.54 mm, and wherein at least one of the power contact pins is in physical contact with one of the plurality of PCB power contact pads.

5. The system of claim 1, wherein the pin pitch between adjacent power pins and data pins is approximately 5.08 mm.

6. The system of claim 1, wherein the male connector includes a main body portion composed of electrically insulating material, wherein the main body portion includes a generally planar upper part, a generally planar bottom part, a forward surface, and a rear surface, the rear surface having an attachment tab extending therefrom, and wherein the male connector is operably attached to the PCB via the attachment tab and the data contact pins.

7. The system of claim 6, wherein each of the data contact pins is bonded to a PCB contact pad.

8. The system of claim 7, wherein the attachment tab includes a solder pin extending therefrom, wherein the PCB includes an aperture sized to receive a portion of the solder pin, and wherein the attachment tab is operably attached to the PCB via the solder pin.

9. The system of claim 8, wherein the solder pin is bonded to the PCB.

10. The system of claim 6, wherein the disc drive includes a base having a front wall and a lower surface, wherein the PCB is operably connected to the lower surface of the base in a manner such the PCB extends beyond the front wall of the base and away from disc drive, and wherein the attachment tab is positioned adjacent to the front wall of the base.

11. The system of claim 6, further comprising two laterally spaced pin compartments integral with the main body portion of the male connector and extending from the forward surface of the main body portion, wherein the data pins are positioned within a first of the laterally spaced pin compartments and wherein the power pins are positioned within a second of the laterally spaced pin compartments.

12. The system of claim 11, further comprising a power cable having a female connector including a set of pin-receptacles, a male connector including a set of male pins, and one or more electrical conductors electrically connecting each of the pins in the set of male pins to one or more of the pin receptacles, wherein the female connector is sized to fit within the second of the laterally spaced pin compartments, and wherein the male connector is sized for mating with a female connector configured for mating with a 3-in-1 ATA interface power connector compartment.

13. A system for employing a 2.5 inch form factor disc drive in computing environments configured for 3.5 inch form factor disc drives, comprising:
a 2.5 inch form factor disc drive having a disc drive printed circuit board (PCB), the PCB including a plurality of PCB data contact pads and a plurality of PCB power contact pads;
a male connector comprising a main body defining two laterally spaced pin compartments;
a plurality of data pins positioned within a first of the laterally spaced pin compartments;
a plurality of data contact pins extending from the main body, each of the plurality of data contact pins electrically connecting to an associated one of the plurality of data pins, wherein each of the data contact pins is bonded to a respective PCB data contact pad;
a plurality of power pins positioned within a second of the laterally spaced pin compartments; and
a plurality of power contact pins extending from the main body, each of the plurality of power contact pins electrically connecting to an associated one of the plurality of power pins, wherein each of the power contact pins is bonded to a respective PCB power contact pad.

14. The system of claim 13, wherein the plurality of data pins includes a first row of data pins having a pin pitch of approximately 2.54 mm between adjacent pins and a second row of data pins, wherein the pin pitch between the first row of data pins and the second row of data pins is approximately 2.54 mm.

15. The system of claim 14, wherein the first row of data contact pins includes twenty data pins, wherein the second row of data pins includes a first group of ten data pins having a pin pitch of approximately 2.54 mm between adjacent pins and a second group of nine data pins having a pin pitch of approximately 2.54 mm between adjacent pins, and wherein the pin pitch between adjacent data pins in the first group of data pins and the second group of data pins is approximately 5.08 mm.

16. The system of claim 15, wherein the plurality of power pins includes a first row of power pins having a pin pitch of approximately 2.54 mm between adjacent pins and a second row of power pins having a pin pitch of approximately 2.54 mm between adjacent pins, wherein the pin pitch between the first row of power pins and the second row of power pins is approximately 2.54 mm.

17. The system of claim 16, further comprising a power cable having a female connector including a set of pin-receptacles, a male connector including a set of male pins, and one or more electrical conductors electrically connecting each of the pins in the set of male pins to one or more of the pin receptacles, wherein the female connector is sized to fit within the second of the laterally spaced pin compartments, and wherein the male connector is sized for mating with a female connector configured for mating with a 3-in-1 ATA interface power connector compartment.

18. A system for employing a 2.5 inch form factor disc drive in a computing environment configured for 3.5 inch form factor disc drives, comprising:
a 2.5 inch form factor disc drive including a base and a disc drive printed circuit board (PCB) attached to the base, the PCB including a plurality of data contact pads and a plurality of power contact pads; and
a data connecting means for electrically connecting the data contact pads of the PCB to data pin receptacles in a female ATA 3-in-1 connector.

19. The system of claim 18, wherein the system further comprises power connecting means for electrically connecting the power contact pads of the PCB to power pin receptacles of a female connector configured for mating with an ATA 3-in-1 connector power pin compartment.

20. The system of claim 19, wherein the data connecting means includes a plurality of data pins having a pin pitch of 2.54 mm.
